(19) United States
(12) Patent Application Publication
(10) Pub. No.: US 2026/0006974 A1
(43) Pub. Date: Jan. 1, 2026

(54) DISPLAY PANEL, PREPARATION METHOD OF DISPLAY PANEL, AND DISPLAY DEVICE

(71) Applicant: Xiamen Extremely PQ Display Technology Co., Ltd., Xiamen (CN)

(72) Inventor: YONG FAN, Xiamen (CN)

(21) Appl. No.: 19/321,233

(22) Filed: Sep. 7, 2025

Related U.S. Application Data
(63) Continuation of application No. PCT/CN2024/095194, filed on May 24, 2024.

(30) Foreign Application Priority Data
Jun. 30, 2023 (CN) 2023107919779

(51) Int. Cl. H10H 29/856; H10H 29/01

(52) U.S. Cl. CPC H10H 29/856; H10H 29/012; H10H 29/0363

(57) ABSTRACT

A display panel, a preparation method of the display panel, and a display device are provided. The display panel includes an array substrate, including: a backplane and multiple display units disposed on the backplane; and an optical layer, covering a side of the backplane facing towards the display units. The optical layer includes: multiple reflective portions disposed in one one-to-one correspondence with the display units, each reflective portion surrounds a corresponding display unit and exposes an end of the corresponding display unit facing away from the backplane, and the reflective portions are spaced apart from each other. The optical layer further includes: a light-shielding portion, filled between the reflective portions. The display panel provided can reduce the screen reflectivity while improving the display brightness of the screen.

### CROSS-REFERENCE TO RELATED APPLICATIONS

This application is a continuation of International Patent Application No. PCT/CN2024/095194, filed on May 24, 2024, which claims the priority of Chinese Patent Application No. 202310791977.9, filed on June 30, 2023, both of which are herein incorporated by reference in their entirety.

### TECHNICAL FIELD

The disclosure relates to the field of display technologies, and more particularly to a display panel, a preparation method of a display panel, and a display device.

### BACKGROUND

For non-transparent micro light emitting diode (micro-LED) displays, a higher ambient contrast ratio and a lower reflectivity are required to achieve better image quality. In the related art, to reduce a reflectivity of a display screen, a black light-absorbing material or a circular polarizer is used for encapsulation. However, while absorbing reflected light, the black light- absorbing material or the circular polarizer also absorbs some of the light emitted by the micro- LED chips. As a result, in addition to reducing the reflectivity, the display brightness is also decreased and the display quality is affected consequently. Moreover, efforts to enhance the display brightness may lead to increased power consumption of the display screen and other related issues.

Therefore, it is urgent to provide a new display panel structure to improve the problem in the related art that reducing reflectivity will affect the normal brightness of the display screen and increase energy consumption.

### SUMMARY

In view of the foregoing, in order to overcome the shortcomings in the related art, the disclosure provides a display panel, a preparation method of a display panel, and a display device, which can reduce screen reflectivity while improving display brightness of the display screen.

An embodiment of the disclosure provides a display panel, including: an array substrate, and an optical layer. The array substrate includes a backplane and multiple display units disposed on the backplane. The optical layer is disposed covering a side of the backplane facing towards the multiple display units. The optical layer includes multiple reflective portions disposed in one-to-one correspondence with the multiple display units, each reflective portion surrounds a corresponding display unit and exposes an end of the corresponding display unit facing away from the backplane, and the multiple reflective portions are spaced apart from each other; and the optical layer further includes: a light-shielding portion, filled between the multiple reflective portions.

In an embodiment, the multiple reflective portions include a first reflective portion, the multiple display units include a first display unit surrounded by the first reflective portion, and a surface of the first reflective portion facing away from the backplane has a first width. A surface of the first display unit facing away from the backplane has a second width, and the first width is greater than the second width; and/or, a surface of the first reflective portion connected to the backplane has a third width being greater than the first width.

In an embodiment, the multiple reflective portions further include a second reflective portion adjacent to the first reflective portion; a spacing between sides of the first reflective portion the second reflective portion facing away from the backplane is a fourth width, and the fourth width is greater than the first width.

In an embodiment, a distance between the surface of the first reflective portion facing away from the backplane and the backplane is a first height. A distance between the surface of the first display unit facing away from the backplane and the backplane is a second height being greater than or equal to the first height; and/or, a distance between a surface of the light- shielding portion facing away from the backplane and the backplane is a third height being greater than or equal to the first height.

In an embodiment, a surface of the first reflective portion facing away from the first display unit is an arc-shaped surface.

In an embodiment, a reflectivity of each reflective portion is in a range of 80%-98%; and/or, a reflectivity of the light-shielding portion is less than 5%.

In an embodiment, multiple pixel regions are formed on the backplane. A contact area between a part of the multiple reflective portions in a single one of the multiple pixel regions and the backplane is less than 20% of an area of the single one of the multiple pixel regions; and/or, a contact area between a part of the light-shielding portion in the single one of the multiple pixel regions and the backplane is greater than 80% of the area of the single one of the multiple pixel regions.

In an embodiment, the multiple reflective portions are made of a white reflective adhesive material, and the light-shielding portion is made of a black adhesive material.

In an embodiment, the display panel further includes multiple limiting portions. The multiple limiting portions are connected to the backplane and surround ends of the multiple reflective portions facing towards the backplane in one-to-one correspondence.

In an embodiment, a distance between each limiting portion and the corresponding display unit surrounded by the reflective portion is in a range of 5-15 micrometers.

An embodiment of the disclosure provides a preparation method of a display panel, including:

providing an array substrate, where the array substrate includes a backplane, and multiple display units disposed on the backplane; and

forming an optical layer on a side of the backplane facing towards the multiple display units, where the optical layer includes: multiple reflective portions and a light-shielding portion, the multiple reflective portions are disposed in one-to-one correspondence with the multiple display units, each reflective portion surrounds a corresponding display unit and exposes an end of the corresponding display unit facing away from the backplane, and the light-shielding portion is filled between the multiple reflective portions.

In an embodiment, the forming an optical layer on a side of the backplane facing towards the multiple display units includes:

forming multiple reflective structures encapsulating the multiple display units in one- to-one correspondence on the side of the backplane facing towards the multiple display units, where the multiple reflective structures are spaced apart from each other;

filling a light-shielding material among the multiple reflective structures, where the light-shielding material and the multiple reflective structures together form an optical material layer; and

removing a part of the optical material layer covering ends of the multiple display units facing away from the backplane to expose the ends of the multiple display units facing away from the backplane, thereby forming the optical layer.

In an embodiment, the forming multiple reflective structures encapsulating the multiple display units in one-to-one correspondence on the side of the backplane facing towards the multiple display units includes:

forming the multiple reflective structures by an inkjet printing process or a dispensing process.

In an embodiment, before the forming an optical layer on a side of the backplane facing towards the multiple display units, the preparation method further includes:

forming multiple limiting portions on the backplane in one-to-one correspondence with the multiple display units, where each limiting portion surrounds a corresponding display unit.

An embodiment of the disclosure provides a display device. The display device includes the display panel described above.

The above embodiments of the disclosure have at least one or more of the following beneficial effects. By setting the reflective portions in the optical layer, the reflective portions surrounding the display units and exposing the ends of the display units facing away from the backplane can reflect the light emitted from sides of the display units and then emit the light from the top of the display units. Moreover, by setting the light-shielding portion between the multiple reflective portions, the part of the backplane that does not need to emit light for display can be covered, reducing the reflectivity of the display panel. Therefore, the display panel provided in the embodiments of the disclosure has the effect of reducing the reflectivity while improving the light emission efficiency.

### BRIEF DESCRIPTION OF DRAWINGS

A detailed explanation of the specific embodiments of the disclosure will be provided below in conjunction with the accompanying drawings.

FIG. 1 illustrates a schematic cross-sectional diagram of a display panel according to an embodiment of the disclosure.

FIG. 2 illustrates a schematic dimensional relationship diagram of the display panel illustrated in FIG. 1.

FIG. 3 illustrates a schematic structural diagram of the display panel illustrated in FIG. 1 according to a specific embodiment of the disclosure.

FIG. 4 illustrates a schematic structural diagram of the display panel illustrated in FIG. 1 according to another specific embodiment of the disclosure.

FIG. 5 illustrates a schematic area relationship diagram of a pixel region according to the embodiment of the disclosure.

FIG. 6 illustrates a schematic cross-sectional diagram of a display panel according to another embodiment of the disclosure.

FIG. 7 illustrates a schematic flowchart of a preparation method of a display panel according to an embodiment of the disclosure.

FIG. 8 illustrates a schematic diagram of a part of a process of the preparation method of the display panel according to an embodiment of the disclosure.

FIG. 9 illustrates a schematic structural diagram of a display device according to an embodiment of the disclosure.

Description of reference signs: 100: display panel; 10: array substrate; 11: backplane; 111: pixel region; 12: display unit; 121: first display unit; 122: second display unit; 20: optical layer; 21: reflective portion; 211: first reflective portion; 2110: arc-shaped surface; 212: second reflective portion; 22: light-shielding portion; 30: limiting portion; 40: encapsulation adhesive layer; 50: cover plate; 60: optical material layer; 61: reflective structure; 62: light-shielding material; 200: display device.

### DETAILED DESCRIPTION OF EMBODIMENTS

In order to make the above objectives, features, and advantages of the disclosure more comprehensible and understandable, a detailed explanation of the specific embodiments of the disclosure will be provided below in conjunction with the accompanying drawings.

In order to enable those skilled in the art to better understand the technical solution of the disclosure, a clear and complete description of the technical solution in the embodiments of the disclosure will be provided below in conjunction with the accompanying drawings. Apparently, the described embodiments are only a part of the embodiments of the disclosure, not all of them. Based on the embodiments in the disclosure, all other embodiments obtained by those skilled in the art without creative labor should fall within the scope of protection of the disclosure.

It should be noted that the terms "first", "second", etc. in the specification, claims, and the accompanying drawings of the disclosure, are used to distinguish similar objects and do not necessarily need to be used to describe a specific order or sequence. It should be understood that the terms used in this way may be interchangeable in appropriate circumstances, so that the embodiments described herein can be implemented in order other than those illustrated or described herein. In addition, the terms "including" and "having", as well as any variations thereof, are intended to cover non-exclusive inclusions, such as processes, methods, systems, products, or devices that contain a series of steps or units that are not necessarily limited to those clearly listed, but may include other steps or units that are not clearly listed or inherent to these processes, methods, products, or devices.

It should be noted that the division of multiple embodiments in the disclosure is only for the convenience of description and should not constitute a special limitation. The features of various embodiments can be combined and referenced to each other without contradiction.

In the related art, there are three methods to reduce the reflectivity of micro-LED display screens as follows. (1) The black adhesive is used for encapsulation, which causes the black adhesive to absorb light emitted from sides of the chip, including light that would otherwise be reflected from the sides of the chip and emitted from the top of the chip, resulting in a reduction in display brightness. In addition, the light absorbed by the adhesive increases the heat of the display panel, which is not conducive to the heat dissipation of the display panel. (2) The lens adhesive and the circular polarizer are used for encapsulation, which causes the circular polarizer to absorb not only the reflected ambient light but also more than 55% of the light emitted from the chip, resulting in a reduction in brightness or an increase in power consumption to boost brightness. (3) A patterned black matrix (BM) layer is fabricated on the cover plate, with light-emitting holes created at positions of the Micro-LED chips, which requires precise bonding processes and is costly to produce.

### FIRST EMBODIMENT

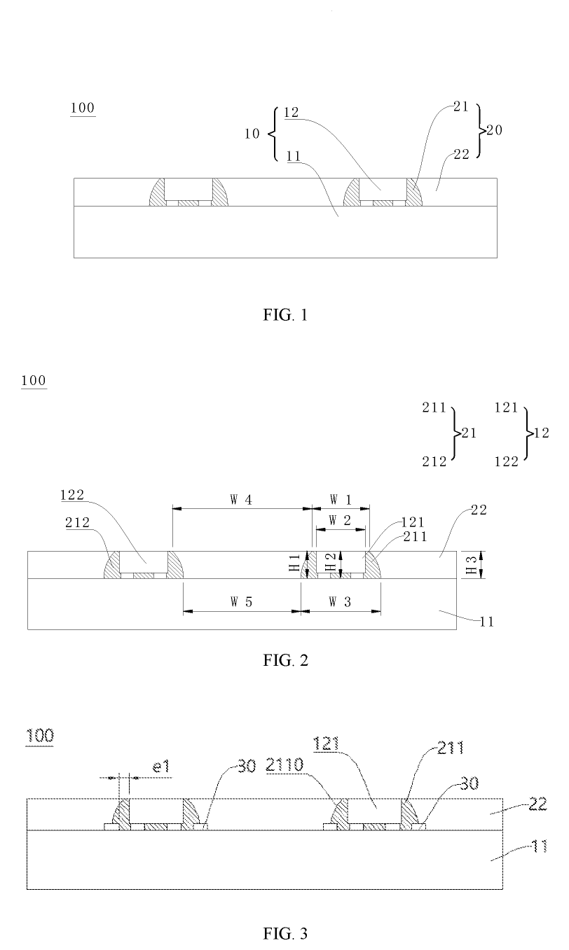

In order to compensate for at least some of the deficiencies in the above-mentioned related art, a first embodiment of the disclosure provides a display panel 100. Referring to FIG. 1, the display panel 100 includes an array substrate 10 and an optical layer 20. The array substrate 10 includes a backplane 11 and multiple display units 12 disposed on the backplane 11. The optical layer 20 covers a side of the backplane 11 facing towards the multiple display units 12. The optical layer 20 includes multiple reflective portions 21 and a light-shielding portion 22. The reflective portions 21 are disposed in one one-to-one correspondence with the display units 12, each reflective portion 21 surrounds a corresponding display unit 12 and exposes an end of the corresponding display unit 12 facing away from the backplane 11, and the reflective portions 21 are spaced apart from each other. The light-shielding portion 22 is filled between the reflective portions 21.

A display unit 12 may include one or more light-emitting devices, such as micro-LED chips. The backplane 11 is provided with, for example, driving circuits configured to drive the light-emitting devices in the display units 12 to emit light and bonding electrodes for the light- emitting devices in the display units 12 to be welded and bonded. The display units 12 may be electrically connected to their respective driving circuits via the bonding electrodes on the backplane 11. As shown in FIG. 1, the display unit 12 includes a light-emitting device. However, in some embodiments, when multiple light-emitting devices are positioned close to each other, the multiple light-emitting devices may be regarded as a display unit 12. For example, the backplane 11 is provided with multiple pixels, each pixel includes multiple color sub-pixels. The multiple color sub-pixels are provided with light-emitting devices of different colors, such as red (R), green (G), and blue (B) light-emitting devices. The light-emitting devices in the blue sub-pixel may be regarded as a display unit 12, the light-emitting devices in the green sub-pixel may be regarded as a display unit 12, and the light-emitting devices in the red sub-pixel may be regarded as a display unit 12. Alternatively, for example, each sub-pixel is provided with a main light-emitting device and a redundant light-emitting device. The main light-emitting device and the redundant light-emitting device may be regarded as a display unit 12. Alternatively, the backplane 11 is provided with multiple light-emitting devices, and each of the multiple light-emitting devices may be regarded as a display unit 12.

The multiple reflective portions 21 are disposed in one-to-one correspondence with the multiple display units 12, that is, each reflective portion 21 surrounds a corresponding display unit 12. Each display unit 12 includes one or more light-emitting devices, that is, there may be one or more light-emitting devices within the corresponding reflective portion 21. In other words, the backplane 11 is provided with multiple light-emitting devices, and the light-emitting devices located within the same reflective portion 21 are regarded as a display unit 12.

Any display unit 12 is surrounded by the corresponding reflective portion 21. An end of each display unit 12 facing away from the backplane 11, that is, a top of each display unit 12, is exposed outside the corresponding reflective portion 21. The multiple reflective portions 21 may be made of a white reflective adhesive material, and a reflectivity of each reflective portion 21 is in a range of 80%-98%. Each reflective portion 21 can reflect the light emitted from the side of the corresponding display unit 12 (i.e., the surface surrounded by the reflective portion 21) and ultimately emit the light from the top of the corresponding display unit 12. Therefore, the light from the side of the display unit 12 can be fully utilized to improve light efficiency.

The light-shielding portion 22 is filled between the multiple reflective portions 21. It should be noted that in some specific embodiments, the light-shielding portion 22 also covers a part between a reflective portion 21 located close to an edge of the backplane 11 and the edge of the backplane 11, such that the regions on the surface of the backplane 11 that are not provided with the reflective portions 21 (i.e., the regions not covered by the multiple reflective portions 21) are all covered by the light-shielding portion 22. In other words, the light-shielding portion 22 surrounds the multiple reflective portions 21 and exposes the surfaces of the multiple reflective portions 21 facing away from the backplane 11. The light-shielding portion 22 can be made of a black adhesive material, a reflectivity of the light-shielding portion 22 is less than 5%, and the light-shielding portion 22 can prevent ambient light outside the display panel 10 from being incident on the backplane 11 and being reflected, thereby reducing the reflectivity of the display panel 100 and improving the display effect.

In the embodiment, by setting up the optical layer 20, the light emitted from the sides of the multiple display units 12 is reflected by the multiple reflective portions 21 in the optical layer 20 to improve light efficiency. Meanwhile, the light-shielding portion 22 in the optical layer 20 absorbs light to reduce the reflectivity. This not only reduces the reflectivity without affecting the normal brightness but also fully utilizes the side light of the light-emitting devices to enhance light efficiency.

In the display panel 100, the multiple display units 12 can be identical or different from each other, and the multiple reflective portions 21 can also be identical or different. Therefore, for the convenience in description, the structure of one reflective portion 21 and the corresponding display unit 12 will be explained in this embodiment to illustrate the specific structure of the display panel 100 provided in this embodiment.

As shown in FIG. 2, the reflective portions 21 include a first reflective portion 211, the display units 12 include a first display unit 121 surrounded by the first reflective portion 211. The remaining multiple reflective portions 21 and the remaining multiple display units 12 can all be designed by referring to the structure of the first reflective portion 211 and the first display unit 121.

In some embodiments, as shown in FIG. 2, a surface of the first reflective portion 211 facing away from the backplane 11 has a first width W1. A surface of the first display unit 121 facing away from the backplane 11 has a second width W2, and the first width W1 is greater than the second width W2. The surface of the first reflective portion 211 facing away from the backplane 11 can be referred to as the top surface of the first reflective portion 211. For example, if a shape of the top surface of the first reflective portion 211 is circular, then the first width W1 can be understood as a diameter of the top surface of the first reflective portion 211. When the top surface of the first reflective portion 211 has a shape other than circular, such as rectangular, the first width W1 can be understood as a diameter of an inscribed circle in the shape of the top surface of the first reflective portion 211. The surface of the first display unit 121 facing away from the backplane 11 can be referred to as the top surface of the first display unit 121. When the first display unit 121 consists of a single light-emitting device, and considering that a micro- LED chip is typically rectangular, the second width W2 can be understood as a maximum width of a rectangle of the top surface of the light-emitting device. Alternatively, when the first display unit 121 includes multiple light-emitting devices, the second width W2 can be understood as a diameter of a circumcircle of the top surfaces of the multiple light-emitting devices. In other words, on any projection plane perpendicular to the backplane 11, the width of the side of the first reflective portion 211 facing away from the backplane 11 in its orthogonal projection is greater than the width of the side of the first display unit 121 facing away from the backplane 11 in its orthogonal projection. This ensures that the top surface of the first display unit 121 is fully exposed outside the first reflective portion 211, allowing the first display unit 121 to fully emit light through its top surface, thereby guaranteeing the light-emitting area and improving the light-emitting effect of the display panel 100. The second width W2 is, for example, greater than 3 micrometers.

Referring to FIG. 2, a surface of the first reflective portion 211 connected to the backplane 11 has a third width W3. In an embodiment, the third width W3 is greater than the first width W1. The surface of the first reflective portion 211 connected to the backplane 11 can be referred to as the bottom surface of the first reflective portion 211. For example, if the shape of the bottom surface of the first reflective portion 211 is circular, then the third width W3 is the diameter of the bottom surface of the first reflective portion 211. It can be understood that in a cross-section (or projection plane) perpendicular to the backplane 11, the width of the side of the first reflective portion 211 near the backplane 11 in its cross-section (or orthogonal projection) is greater than the width of the side facing away from the backplane 11. Referring to the orientation in FIG. 2, the first reflective portion 211 has a shape that is narrower at the top and wider at the bottom. The wider bottom surface of the first reflective portion 211 can collect more side light, and the narrower top surface of the first reflective portion 211 can make the region that can reflect ambient light outside the display panel 100 smaller, achieving a better effect of reducing reflectivity. As shown in FIGS. 1 and 2, the surface of the first reflective portion 211 facing away from the first display unit 121 is an arc-shaped surface 2110, and thus the first reflective portion 211 has an arch-like structure in the cross-section shown in FIG. 1. Of course, in some embodiments, the surface of the first reflective portion 211 can also be a plane, in which case the cross-section (a cross-section perpendicular to the backplane 11) of the first reflective portion 211 has a shape of a right trapezoid that is narrower at the top and wider at the bottom (not shown in figures).

Of course, in some embodiments, the third width W3 can also be less than the first width W1. In this case, when the surface of the first reflective portion 211 facing away from the first display unit 121 is an arc-shaped surface 2110, the cross-section of the first reflective portion 211 presents a bowl-like structure. When the surface of the first reflective portion 211 is planar, the cross-section of the first reflective portion 211 presents an inverted trapezoidal structure that is wider at the top and narrower at the bottom. Alternatively, in some embodiments, the third width W3 can also be equal to the first width W1. This embodiment does not impose any limitations in this regard.

In some embodiments, referring to FIG. 2, the multiple reflective portions 21 further include a second reflective portion 212 adjacent to the first reflective portion 211. It can be understood that the reflective portion 21 adjacent to the first reflective portion 211 is designated as the second reflective portion 212. Alternatively, it can be understood that among the multiple reflective portions 21, two adjacent reflective portions 21 are respectively designated as the first reflective portion 211 and the second reflective portion 212, with the second reflective portion 212 surrounding the second display unit 122. A spacing between sides of the first reflective portion 211 and the second reflective portion 212 facing away from the backplane 11 is the fourth width W4. In an embodiment, the fourth width W4 is greater than the first width W1. The fourth width W4 can be understood as a minimum distance between the top surface of the first reflective portion 211 and the top surface of the second reflective portion 212. The fact that the fourth width W4 is greater than the first width W1 can be understood as follows: in any cross-section (or projection plane) perpendicular to the backplane 11, the distance between the top of the cross-section (or orthogonal projection) of the first reflective portion 211 and the top of the cross-section (or orthogonal projection) of the second reflective portion 212 is greater than the width of the top of the cross-section (or orthogonal projection) of the first reflective portion 211.

Referring to FIG. 2, a distance between the surface of the first reflective portion 211 facing away from the backplane 11 and the backplane 11 is a first height H1. A distance between the surface of the first display unit 121 facing away from the backplane 11 and the backplane 11 is a second height H2. The distance between the surface of the light-shielding portion 22 facing away from the backplane 11 and the backplane 11 is a third height H3. In some embodiments, the second height H2 is greater than or equal to the first height H1 to ensure the light-emitting effect from the top surface of the first display unit 121. In some embodiments, the third height H3 is greater than or equal to the first height H1 to ensure that the light-shielding portion 22 fully encloses and covers the first reflective portion 211, reducing the issue of reflection from the outer surface of the first reflective portion 211. The second height H2, for example, is less than 15 micrometers.

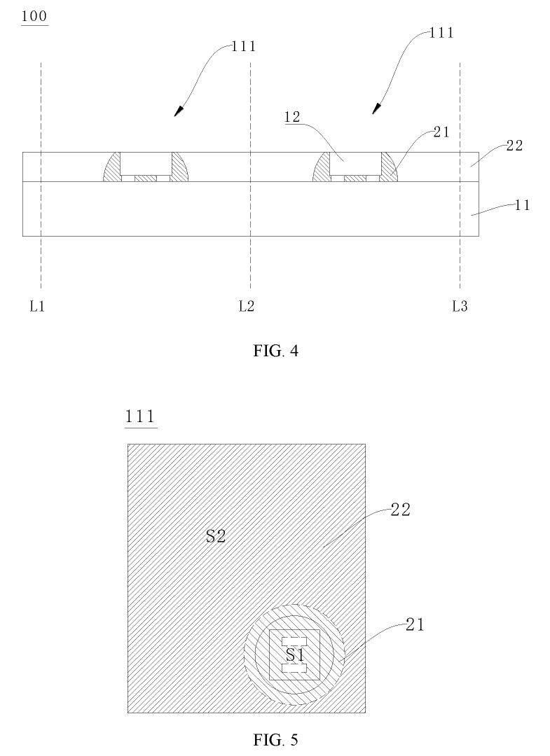

In an embodiment, the backplane 11 is formed with multiple pixel regions 111. Referring to FIG. 4 , a region between the dashed line Li and the dashed line L2 is a pixel region 111, and a region between the dashed line L2 and the dashed line L3 is another pixel region 111. A pixel region 111 can be understood as a region corresponding to the pixel in the aforementioned embodiments. Within each pixel region 111, it is necessary to reduce the reflection from the regions on the backplane 11 other than where the display units 12 are located. A contact area between a part of the reflective portions 21 in a single pixel region 111 and the backplane 11 is less than 20% of an area of the single pixel region 111. FIG. 5 shows a top view structural diagram of a single pixel region. This pixel region 111, for example, includes one reflective portion 21. The circular dashed line represents the contour line of the contact surface (bottom surface) of the reflective portion 21 with the backplane 11. The circular solid line represents the contour line of the top surface of the reflective portion 21. The rectangular solid line represents the contour line of the top surface of the display unit 12. The two rectangular dashed lines represent the contour lines of the bonding pads of the display unit 12, that is, the contour lines of the contact surface of the display unit 12 with the backplane 11. The area of this pixel region 111 is denoted as SO, the contact area between the reflective portion 21 and the backplane 11 within this pixel region 111 is denoted as S1 (which can also be referred to as the coverage area of the reflective portion 21 within a single pixel region), the contact area between the light-shielding portion 22 located within this pixel region 111 and the backplane 11 is denoted as S2, and the contact area between the display unit 12 and the backplane 11 is S3 (the area within the two rectangular dashed lines in the pixel region 111 in FIG. 5, not filled with diagonal lines). The area enclosed by the circular dashed line is denoted as S4 (not marked in the figure). The area filled with right diagonal lines in FIG. 5 represents the contact area S1 between the reflective portion 21 and the backplane 11 within this pixel region 111. S1=S4-S3, that is, the coverage area of the reflective portion 21 within a single pixel region does not include the contact area between the display unit 12 and the backplane 11. In some embodiments, S1 is less than 20% of SO. Within this pixel region 111, the remaining region other than where the reflective portion 21 is located is covered by the light-shielding portion 22. In some embodiments, the contact area between a part of the light-shielding portion 22 located within a single pixel region 111 and the backplane 11 is greater than 80% of the area of the single pixel region 111, that is, S2 is greater than 80% of SO. As shown in FIG. 5, the part of the pixel region 111 excluding the area S4 enclosed by the circular dashed line is the contact area S2 between the part of the light-shielding portion 22 located within this pixel region 111 and the backplane 11 (which can also be understood as the coverage area of the light-shielding portion 22 within a single pixel region 111). The area filled with left diagonal lines in FIG. 5 is S2, that is, S2=SO-S4. S2 is greater than 80% of SO to better reduce the reflection of ambient light from outside the display panel 100.

In some embodiments, as shown in FIG. 3, the display panel 100 further includes multiple limiting portions 30, which are connected to the backplane 11. These limiting portions 30 are arranged to surround the ends of the reflective portions 21 facing towards the backplane 11 in one-to-one correspondence, that is, a bottom of each reflective portion 21 is surrounded by a limiting portion 30. The height of the limiting portion 30, measured from the backplane 11 to a surface of the limiting portion 30 facing away from the backplane 11, is less than the second height H2. The limiting portion 30 can be a continuous or discontinuous annular structure and can be made of transparent resin or other transparent adhesive materials that can be prepared using processes such as photolithography or printing. During the formation of the reflective portion 21, the limiting portion 30 can play a limiting role to the formation material of the reflective portion 21, ensuring the thickness of the reflective portion 21 corresponding to the display unit 12.

In some specific embodiments, the distance el (referring to FIG. 3) between any limiting portion 30 and the corresponding display unit 12 surrounded by the reflective portion 21 is in a range of 5-15 micrometers. Each limiting portion 30 surrounds one reflective portion 21, and each reflective portion 21 surrounds one display unit 12. That is to say, each limiting portion 30 surrounds a display unit 12 and is spaced from the display unit 12, with a spacing distance of 5-15 micrometers. This can better achieve the utilization of side light, improve the utilization rate of light energy, and reduce power consumption.

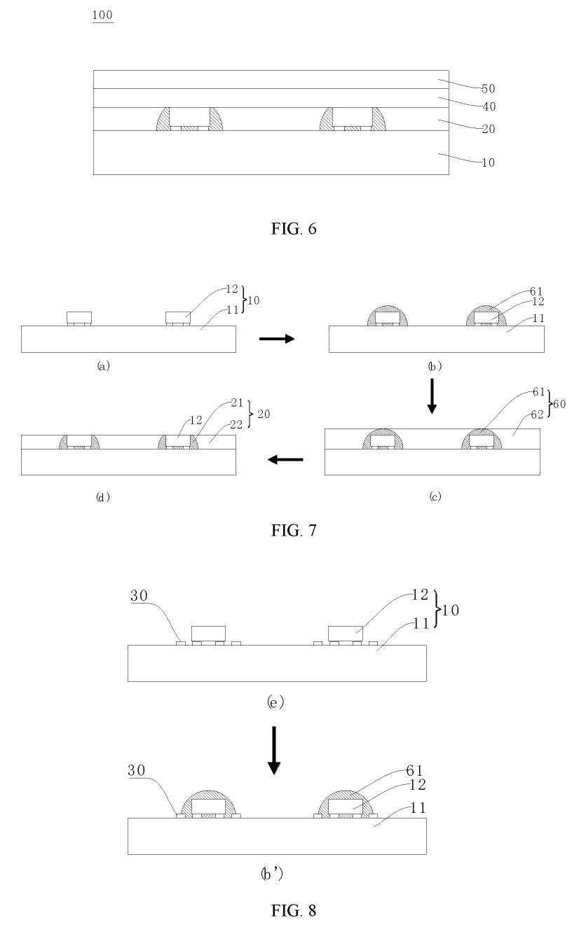

In some embodiments, referring to FIG. 6 , the display panel 100 further includes an encapsulation adhesive layer 40 and a cover plate 50. The encapsulation adhesive layer 40 covers the sides of the multiple display units 12 and the optical layer 20 facing away from the backplane 11. The cover plate 50 covers the side of the encapsulation adhesive layer 40 facing away from the optical layer 20. The material of the encapsulation adhesive layer 40 can be a commonly used transparent encapsulation adhesive, and the cover plate 50, for example, can be a glass plate, which can provide protection for the display panel 100.

### SECOND EMBODIMENT

A second embodiment of the disclosure provides a preparation method of a display panel, which can be used to prepare the display panel 100 in the first embodiment. The preparation method includes the following steps S1 and S3.

S1, an array substrate 10 is provided, where the array substrate 10 includes a backplane 11, and multiple display units 12 disposed on the backplane 11.

S3, an optical layer 20 is formed on a side of the backplane 11 facing towards the display units 12, where the optical layer 20 includes: multiple reflective portions 21 disposed in one- to-one correspondence with the display units 12, each reflective portion 21 surrounds a corresponding display unit 12 and exposes an end of the corresponding display unit 12 facing away from the backplane 11; and the optical layer 20 further includes: a light-shielding portion 22, filled between the reflective portions 21.

The preparation method of the display panel provided in this embodiment can be used to prepare the display panel 100 described in the first embodiment mentioned above, and therefore has the same beneficial effects as those described in the first embodiment.

More specifically, step Si refers to step (a) in FIG. 7. For example, light-emitting devices of the multiple display units 12 are bonded on the backplane 11 by means such as welding to obtain the array substrate 10.

In some specific embodiments, referring to FIG. 7, step S3 specifically includes the following steps S31-S35.

S31 (step (b) in FIG. 7 or step (b') in FIG. 8), multiple reflective structures 61 are formed encapsulating the display units 12 in one-to-one correspondence on the side of the backplane 11 facing towards the display units 12, where the reflective structures 61 are spaced apart from each other.

S33 (step (c) in FIG. 7), a light-shielding material 62 is filled among the multiple reflective structures 61, where the light-shielding material 62 and the reflective structures 61 together form an optical material layer 60.

S35 (step (d) in FIG. 7), a part of the optical material layer 60 covering ends of the display units 12 facing away from the backplane 11 is removed to expose the ends of the display units 12 facing away from the backplane 11 to thereby form an optical layer 20.

Specifically, in step S31, the multiple reflective structures 61 can be formed through an inkjet printing (IJP) process or a dispensing process. The reflective adhesive material is printed on the backplane 11 in correspondence with the multiple display units 12, forming the multiple reflective structures 61 as shown in step (b) of FIG. 7 .

In step S33, the light-shielding material 62 is coated onto the array substrate 10 formed with the multiple reflective structures 61, so that the light-shielding material 62 covers the multiple reflective structures 61 and the parts of the backplane 11 exposed outside the multiple reflective structures 61. The light-shielding material 62 and the multiple reflective structures 61 together form the optical material layer 60 as shown in step (c) of FIG. 7 . In step S35, for example, an etching process is used to remove the part of the optical material layer 60 that covers the tops of the multiple display units 12, exposing the ends of the multiple display units 12 facing away from the backplane, forming the optical layer 20 as shown in step (d) of FIG.7.

In this embodiment, the multiple reflective structures 61 can be formed through the IJP process or the dispensing process. The optical layer 20 can be formed as a whole through a few etching processes. The process is simple, can utilize existing process equipment, and does not require high-precision alignment, resulting in lower production costs. Of course, in some other embodiments, after forming the multiple reflective structures 61 in step S31, the multiple reflective structures 61 can first be processed to form the multiple reflective portions 21 before forming the light-shielding portion 22. This embodiment does not impose any limitations.

In some embodiments, before step S3, the preparation method further includes step S2, multiple limiting portions 30 are formed on the backplane 11 in one-to-one correspondence with the display units 12, where each limiting portion 30 surrounds a corresponding display unit 12. The structure shown in step (e) of FIG. 8 is obtained after step S2. The multiple limiting portions 30 can be formed, for example, using the transparent adhesive material through the inkjet printing process. In step S33, the reflective structures 61 are formed within the limiting portions 30 using the inkjet printing or dispensing process to obtain the structure shown in step(b') of FIG. 8. This can limit the thickness of the reflective structure 61 wrapping around the side of each display unit 12, ensuring the collection effect of the side light of each display unit 12. In some specific embodiments, the distance from each limiting portion 30 to the corresponding display unit 12 is 5-15 micrometers, which can achieve better light efficiency.

### THIRD EMBODIMENT

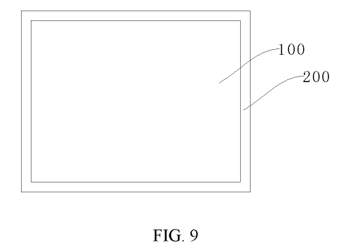

Referring to FIG. 9, a third embodiment of the disclosure provides a display device 200, which includes the display panel 100 described in the first embodiment or the display panel 100 prepared by the preparation method described in the second embodiment. It has the same beneficial effects as those described in the first and second embodiments. The display device 200 can be, for example, electronic devices with display functions such as mobile phones, computers, tablets, and smartwatches. The display device 200 may further include, for example, a control circuit board and even other necessary structures for controlling the operation of the display panel 100. The setting of these necessary structures can be referred to the setting of conventional display devices, and will not be described one by one in this embodiment.

What has been described above is merely the exemplary embodiments of the disclosure and is not intended to limit the disclosure in any form. Although the disclosure has been disclosed in the above exemplary embodiments, it is not intended to be limited thereby. Any person skilled in the art, without departing from the scope of the technical solution of the disclosure, may make some modifications or refinements based on the disclosed technical content, or make equivalent embodiments through equivalent changes. Any simple modifications, equivalent changes, and decorations made to the above embodiments without departing from the content of the technical solution of the disclosure, in accordance with the technical essence of the disclosure, shall still fall within the scope of the technical solution of the disclosure.

What is claimed is:

1. A display panel, comprising:
an array substrate, comprising: a backplane, and a plurality of display units disposed on the backplane; and
an optical layer, disposed covering a side of the backplane facing towards the plurality of display units, and comprising:a plurality of reflective portions disposed in one-to-one correspondence with the plurality of display units, wherein each of the plurality of reflective portions surrounds a corresponding one of the plurality of display units and exposes an end of the corresponding one of the plurality of display units facing away from the backplane, and the plurality of reflective portions are spaced apart from each other; anda light-shielding portion, filled between the plurality of reflective portions.

2. The display panel as claimed in claim 1, wherein the plurality of reflective portions comprise a first reflective portion, the plurality of display units comprise a first display unit surrounded by the first reflective portion, and a surface of the first reflective portion facing away from the backplane has a first width; and
wherein a surface of the first display unit facing away from the backplane has a second width, and the first width is greater than the second width; and/or, a surface of the first reflective portion connected to the backplane has a third width being greater than the first width.

3. The display panel as claimed in claim 2, wherein the plurality of reflective portions further comprise a second reflective portion adjacent to the first reflective portion; a spacing between sides of the first reflective portion and the second reflective portion facing away from the backplane is a fourth width, and the fourth width is greater than the first width.

4. The display panel as claimed in claim 2, wherein a distance between the surface of the first reflective portion facing away from the backplane and the backplane is a first height; and
wherein a distance between the surface of the first display unit facing away from the backplane and the backplane is a second height being greater than or equal to the first height; and/or, a distance between a surface of the light-shielding portion facing away from the backplane and the backplane is a third height being greater than or equal to the first height.

5. The display panel as claimed in claim 2, wherein a surface of the first reflective portion facing away from the first display unit is an arc-shaped surface.

6. The display panel as claimed in claim 1, wherein a reflectivity of each of the plurality of reflective portions is in a range of 80%-98%; and/or, a reflectivity of the light-shielding
portion is less than 5%.

7. The display panel as claimed in claim 1, wherein a plurality of pixel regions are formed on the backplane, and
wherein a contact area between a part of the plurality of reflective portions in a single one of the plurality of pixel regions and the backplane is less than 20% of an area of the single one of the plurality of pixel regions; and/or, a contact area between a part of the light-shielding portion in the single one of the plurality of pixel regions and the backplane is greater than 80% of the area of the single one of the plurality of pixel regions.

8. The display panel as claimed in claim 1, wherein the plurality of reflective portions are made of a white reflective adhesive material, and the light-shielding portion is made of a black adhesive material.

9. The display panel as claimed in claim 1, further comprising a plurality of limiting portions, wherein the plurality of limiting portions are connected to the backplane and surround ends of the plurality of reflective portions facing towards the backplane in one-to-one correspondence.

10. The display panel as claimed in claim 9, wherein a distance between each of the plurality of limiting portions and the corresponding one of the plurality of display units surrounded by the reflective portion is in a range of 5-15. micrometers.

11. A preparation method of a display panel, comprising:
providing an array substrate, wherein the array substrate comprises a backplane, and a plurality of display units disposed on the backplane; and
forming an optical layer on a side of the backplane facing towards the plurality of display units, wherein the optical layer comprises a plurality of reflective portions and a light-shielding portion, the plurality of reflective portions are disposed in one-to-one correspondence with the plurality of display units, each of the plurality of reflective portions surrounds a corresponding one of the plurality of display units and exposes an end of the corresponding one of the plurality of display units facing away from the backplane, and the light-shielding portion is filled between the plurality of reflective portions.

12. The preparation method of the display panel as claimed in claim 11, wherein the forming an optical layer on a side of the backplane facing towards the plurality of display units comprises:
forming a plurality of reflective structures encapsulating the plurality of display units in one-to-one correspondence on the side of the backplane facing towards the plurality of display units, wherein the plurality of reflective structures are spaced apart from each other;
filling a light-shielding material among the plurality of reflective structures, wherein the light-shielding material and the plurality of reflective structures together form an optical material layer; and
removing a part of the optical material layer covering ends of the plurality of display units facing away from the backplane to expose the ends of the plurality of display units facing away from the backplane, thereby forming the optical layer.

13. The preparation method of the display panel as claimed in claim 12, wherein the forming a plurality of reflective structures encapsulating the plurality of display units in one- to-one correspondence on the side of the backplane facing towards the plurality of display units comprises:
forming the plurality of reflective structures by an inkjet printing process or a dispensing process.

14. The preparation method of the display panel as claimed in claim 11, before the forming an optical layer on a side of the backplane facing towards the plurality of display units, further comprising:
forming a plurality of limiting portions on the backplane in one-to-one correspondence with the plurality of display units, wherein each of the plurality of limiting portions surrounds the corresponding one of the plurality of display units.

15. A display device, comprising: the display panel as claimed in claim 1.

16. The display device as claimed in claim 15, wherein in the display panel, the plurality of reflective portions comprise a first reflective portion, the plurality of display units comprise a first display unit surrounded by the first reflective portion, and a surface of the first reflective portion facing away from the backplane has a first width; and
wherein a surface of the first display unit facing away from the backplane has a second width, and the first width is greater than the second width; and/or, a surface of the first reflective portion connected to the backplane has a third width being greater than the first width.

17. The display device as claimed in claim 16, wherein in the display panel, the plurality of reflective portions further comprise a second reflective portion adjacent to the first reflective portion; a spacing between sides of the first reflective portion and the second reflective portion facing away from the backplane is a fourth width, and the fourth width is greater than the first width.

18. The display device as claimed in claim 16, wherein in the display panel, a distance between the surface of the first reflective portion facing away from the backplane and the backplane is a first height; and
wherein a distance between the surface of the first display unit facing away from the backplane and the backplane is a second heigh being greater than or equal to the first height; and/or, a distance between a surface of the light-shielding portion facing away from the backplane and the backplane is a third height being greater than or equal to the first height.

19. The display device as claimed in claim 15, wherein in the display panel, a plurality of pixel regions are formed on the backplane, and
wherein a contact area between a part of the plurality of reflective portions in a single one of the plurality of pixel regions and the backplane is less than 20% of an area of the single one of the plurality of pixel regions; and/or, a contact area between a part of the light-shielding portion in the single one of the plurality of pixel regions and the backplane is greater than 80% of the area of the single one of the plurality of pixel regions.

20. The display device as claimed in claim 15, wherein the display panel further comprises a plurality of limiting portions which are connected to the backplane and surround ends of the plurality of reflective portions facing towards the backplane in one-to-one correspondence; and a distance between each of the plurality of limiting portions and the corresponding one of the plurality of display units surrounded by the reflective portion is in a range of 5-15 micrometers.
